(19) United States
(12) Patent Application Publication
(10) Pub. No.: US 2026/0304788 A1
(43) Pub. Date: Oct. 1, 2026

(54) SEMICONDUCTOR DEVICE

(71) Applicant: SK hynix Inc., Icheon-si (KR)

(72) Inventor: Soo Man SEO, Icheon-si (KR)

(21) Appl. No.: 19/705,474

(22) Filed: Jun. 11, 2026

Related U.S. Application Data
(63) Continuation of application No. 17/899,411, filed on Aug. 30, 2022.

(30) Foreign Application Priority Data
Dec. 17, 2021 (KR) 10-2021-0181364

(51) Int. Cl. H10B 63/00; H10B 61/00; H10N 70/00; H10N 70/20

(52) U.S. Cl. CPC H10B 63/80; H10B 61/10; H10B 63/20; H10N 70/821; H10N 70/826; H10N 70/20

(57) ABSTRACT

A semiconductor device includes: a plurality of conductive lines extending in a first direction; and a plurality of memory cells arranged in a plurality of columns extending in a second direction intersecting the first direction, wherein the plurality of columns include odd-numbered columns and even-numbered columns, wherein a specific conductive line among the plurality of conductive lines partially overlaps a first portion of a memory cell in one of the odd-numbered columns and a second portion of a memory cell in one of the even-numbered columns, and wherein the first portion and the second portion face each other with respect to a center line of the specific conductive line.

### PRIORITY CLAIM AND CROSS-REFERENCE TO RELATED APPLICATION

This patent application is a continuation of U.S. patent application Ser. No. 17/899,411, filed on Aug. 30, 2022, which claims priority under 35 U.S.C. § 119 to Korean Patent Application No. 10-2021-0181364, filed on Dec. 17, 2021. The entire disclosures of the foregoing applications are incorporated herein by reference.

### TECHNICAL FIELD

This patent document relates to memory circuits or devices.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes various embodiments of a semiconductor device having excellent operating characteristics and preventing process defects.

In an embodiment, a semiconductor device includes: a plurality of conductive lines extending in a first direction; and a plurality of memory cells arranged in a plurality of columns extending in a second direction intersecting the first direction, wherein the plurality of columns include odd-numbered columns and even-numbered columns, wherein a specific conductive line among the plurality of conductive lines partially overlaps a first portion of a memory cell in one of the odd-numbered columns and a second portion of a memory cell in one of the even-numbered columns, and wherein the first portion and the second portion face each other with respect to a center line of the specific conductive line.

### BRIEF DESCRIPTION OF THE DRAWINGS

FIG. 1A is a plan view illustrating a semiconductor memory of a comparative example.

FIG. 1B is a cross-sectional view taken along a line A1-A1′ of FIG. 1A.

FIG. 1C is a cross-sectional view taken along a line B1-B1′ of FIG. 1A.

FIG. 1D is a plan view illustrating a semiconductor memory of another comparative example.

FIG. 2A is a plan view illustrating a semiconductor memory according to an embodiment of the disclosed technology.

FIG. 2B is a cross-sectional view taken along a line A2-A2′ of FIG. 2A.

FIG. 2C is a cross-sectional view taken along a line B2-B2′ of FIG. 2A.

FIG. 2D is a view showing a part of the memory cell of FIGS. 2A to 2C.

FIG. 3 is a plan view illustrating a semiconductor memory according to another embodiment of the disclosed technology.

FIG. 4A is a plan view illustrating a semiconductor memory according to another embodiment of the disclosed technology.

FIG. 4B is a cross-sectional view taken along a line A4-A4′ of FIG. 4A.

### DETAILED DESCRIPTION

Various embodiments of the disclosed technology will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible.

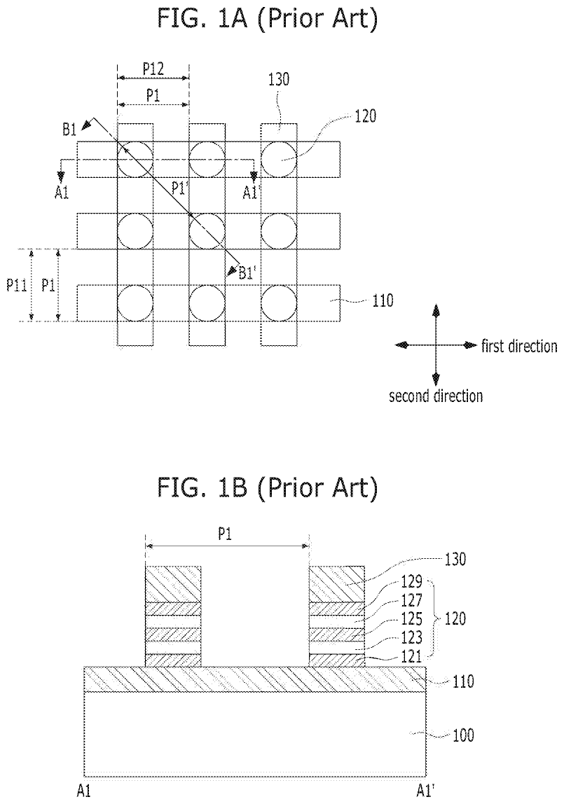

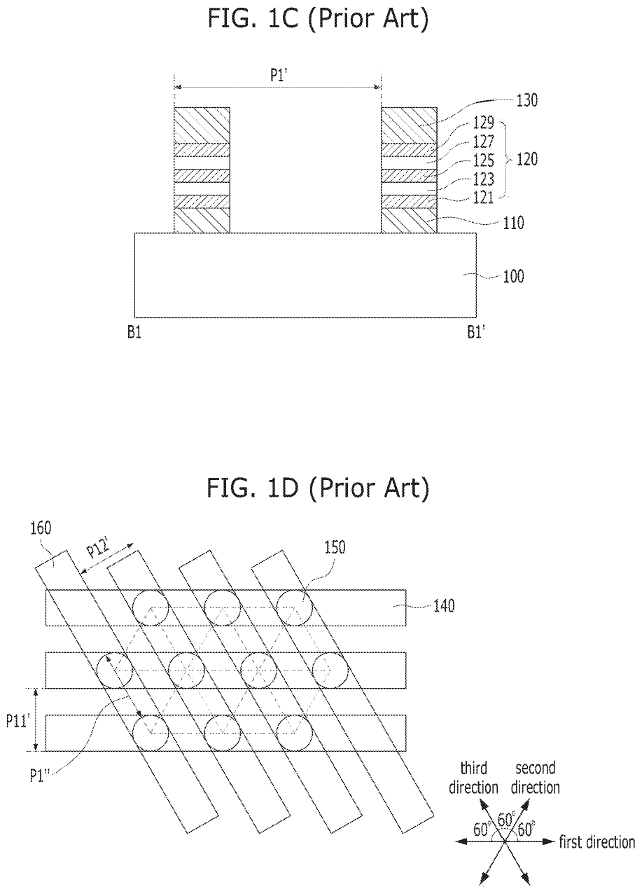

FIG. 1A is a plan view illustrating a semiconductor memory of a comparative example, FIG. 1B is a cross-sectional view taken along a line A1-A1′ of FIG. 1A, and FIG. 1C is a cross-sectional view taken along a line B1-B1′ of FIG. 1A. FIG. 1D is a plan view illustrating a semiconductor memory of another comparative example.

First, referring to FIGS. 1A to 1C, the semiconductor memory of the comparative example may include a substrate 100, a plurality of first conductive lines 110 formed over the substrate 100 and extending in a first direction, a plurality of second conductive lines 130 formed over the first conductive lines 110 to be spaced apart from the first conductive lines 110 and extending in a second direction substantially perpendicular to the first direction, and a plurality of memory cells 120 respectively overlapping intersection regions of the first conductive lines 110 and the second conductive lines 130 between the first conductive lines 110 and the second conductive lines 130.

The memory cell 120 may have a columnar shape and may function to store data. In an example, the memory cell 120 may include a variable resistance element that stores different data by switching between different resistance states according to a voltage or current applied through the lower end and the upper end thereof. In an example, the memory cell 120 may include a multi-layer structure including a lower electrode layer 121, a selection element layer 123, an intermediate electrode layer 125, a variable resistance layer 127, and an upper electrode layer 129.

In such a memory device, the pitch P1 of the memory cells 120 arranged in the first direction or the second direction may be smaller than the pitch P1′ of the memory cells 120 arranged in a direction diagonal to the first direction or the second direction, for example, in the direction of B1-B1′ line. For reference, a pitch refers to a distance from one end of one component to one end of another adjacent component when a plurality of components are arranged in one direction, and it may correspond to the sum of a width of one component and a distance between one component and another adjacent component. Since the width of the memory cell 120 is substantially constant regardless of directions, the distance between adjacent memory cells 120 in the first direction or the second direction may be smaller than the distance between adjacent memory cells 120 in the diagonal direction.

In order to form the columnar memory cell 120, it may be necessary to deposit material layers constituting the memory cell 120 by selectively etching the material layers. When the memory cell 120 has a multi-layer structure in which the variable resistance layer 127 has a multi-layer structure such as a magnetic tunnel junction (MTJ) structure, the difficulty of a suitable etching process for etching such a multi-layer structure into a desired shape may increase and an etching process having excellent anisotropic etching characteristics, for example, an ion beam etching process may be used to achieve the desired etching outcome.

The ion beam etching process, when the distance between the patterns is not constant, is subject to an ion beam shadow phenomenon in which the ion beam does not reach an area having a relatively narrow distance between the patterns. Due to this beam shadow phenomenon, an area having a relatively wide distance between the patterns may be sufficiently etched, while an area having a relatively narrow distance between the patterns may not be less etched. Such a difference in the amount of the material removal due to the spacing between adjacent patterns using the same ion beam etching process is undesirable because it may be difficult to separate the patterns. In the memory device of the comparative example in FIG. 1A, the memory cells 120 adjacent in the diagonal direction having a relatively wide distance may be sufficiently separated due to sufficient etching, whereas the memory cells 120 adjacent in the first direction or the second direction having a relatively narrow distance may not be separated from each other due to less etching.

The comparative example of FIG. 1D is designed to form memory cells 150 in a different way so that with a uniform distance between adjacent cells in different directions, i.e., having a uniform pitch of the memory cells 150 so that the undesired etching using the ion beam etching process in the example in FIG. 1A can be reduced.

Referring to FIG. 1D, the semiconductor memory of another comparative example may include a plurality of first conductive lines 140 extending in a first direction, a plurality of second conductive lines 160 formed over the first conductive lines 140 to be spaced apart from the first conductive lines 140 and extending in a third and different direction forming an angle that is at or substantially around 60 degrees with respect to the first direction, and a plurality of memory cells 150 respectively overlapping intersection regions of the first conductive lines 140 and the second conductive lines 160 between the first conductive lines 140 and the second conductive lines 160. The line spacing and line width of the first conductive lines 140, the line spacing and line width of the second conductive lines 160 are designed to place the spacing between adjacent memory cells 150 at a uniform cell spacing in different directions so that one memory cell 150 in one first conductive line 140 and two closest adjacent memory cells 150 in an adjacent first conductive line 140 form vertices of an equilateral triangle and, similarly, one memory cell 150 in one second conductive line 160 and two closest adjacent memory cells 150 in an adjacent second conductive line 140 form vertices of another equilateral triangle of an identical or nearly identical size.

The above equal cell spacing geometry is illustrated by imaginary dashed lines in FIG. 1D and a plurality of equilateral triangles formed by the adjacent memory cells 150. The equilateral triangles are arranged such that six equilateral triangles form one equilateral hexagon, the plurality of memory cells 150 may be arranged to respectively overlap the vertices of the equilateral triangles. Accordingly, the plurality of memory cells 150 may be arranged in a line along the first direction, the second direction, and the third direction parallel to the three sides of the equilateral triangle, respectively. The second direction may form an angle of substantially 60 degrees with respect to each of the first direction and the third direction. The plurality of memory cells 150 arranged in the first direction may overlap the first conductive line 140, and the plurality of memory cells 150 arranged in the third direction may overlap the second conductive line 160.

In the comparative example of FIG. 1D, the pitch P1″ (i.e., the spacing between two adjacent cells) of the memory cells 150 in the first direction, the second direction, and the third direction may be substantially the same or a constant. Accordingly, the problem of the comparative example of FIG. 1A described above due to the unequal spacing between adjacent cells in the ion beam etching may be solved.

Assuming the same conductive line structures in both examples in FIGS. 1A and 1D, the line pitch P11″ of the first conductive lines 140 and the line pitch P12″ of the second conductive lines 160 in the comparative example of FIG. 1D may be decreased relative to the line pitches P11 and P12 in the comparative example of FIG. 1A. Accordingly, the width of each of the first conductive line 140 and the second conductive line 160 in the comparative example of FIG. 1D may be decreased to achieve the same or similar line spacing as in the comparative example of FIG. 1A. When the widths of the first conductive line 140 and the second conductive line 160 in the comparative example of FIG. 1D are decreased, the resistance of the first conductive line 140 and the second conductive line 160 with the reduced line width may be increased, so the operating characteristics of the semiconductor memory may be deteriorated. This will be described in more detail with an example as follows.

It may be assumed that the pitch P1 of the memory cells 120 in the first direction or the second direction in the comparative example of FIG. 1A and the pitch P1″ of the memory cells 150 in the first direction, the second direction, or the third direction in the comparative example of FIG. 1D have the same value, for example, 2F. In this case, in the comparative example of FIG. 1A, the pitch P11 of the first conductive lines 110 may have the same value as the pitch P1 of the memory cells 120, that is, 2F. On the other hand, in the comparative example of FIG. 1D, the pitch P11′ of the first conductive lines 140 may have a value of 2F*√3/2, that is, about 1.732F. That is, in the comparative example of FIG. 1D, the pitch P11′ of the first conductive lines 140 may be smaller than the pitch P1″ of the memory cell 150. A decrease in the pitch P11′ of the first conductive lines 140 may mean a decrease in the width of the first conductive line 140 and an increase in the resistance thereof. Similarly, in the comparative example of FIG. 1A, the pitch P12 of the second conductive lines 130 may have the same value as the pitch P1 of the memory cells 120, that is, 2F. On the other hand, in the comparative example of FIG. 1D, the pitch P12′ of the second conductive lines 160 may have a value of 2F*√3/2, that is, about 1.732F. That is, in the comparative example of FIG. 1D, the pitch P12′ of the second conductive lines 160 may be smaller than the pitch P1″ of the memory cells 150. A decrease in the pitch P12′ of the second conductive lines 160 may mean a decrease in the width of the second conductive line 160 and an increase in the resistance thereof.

In some embodiments, the conductive line recited in the claims may correspond to the first conductive line 210, the second conductive line 230, the first conductive line 310, the second conductive line 330, the first conductive line 410, or the second conductive line 430.

In recognition of the problems discussed with reference to FIGS. 1A and 1D, the disclosed technology includes various implementations of a semiconductor memory capable of solving both the problem of the comparative example of FIG. 1A and the problem of the comparative example of FIG. 1D. Implementations of the disclosed technology may be used to construct a semiconductor memory capable of preventing and/or minimizing the reduction in the pitch of the conductive lines and the reduction in the width/increase in the resistance of the conductive line while making the pitch of the memory cells constant in different directions to achieve relatively uniform etching during fabrication.

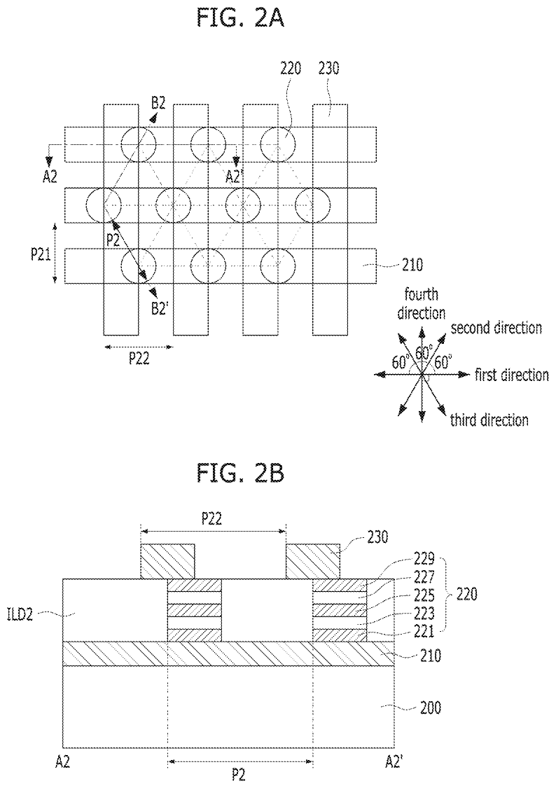

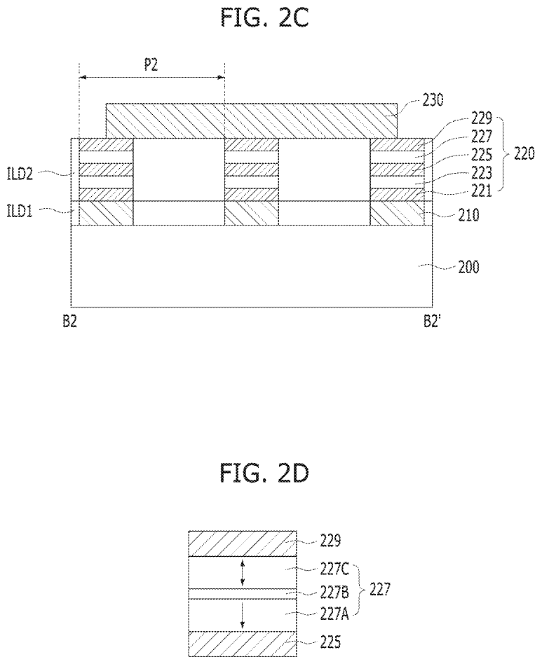

FIG. 2A is a plan view illustrating a semiconductor memory according to an embodiment of the disclosed technology, FIG. 2B is a cross-sectional view taken along a line A2-A2′ of FIG. 2A, and FIG. 2C is a cross-sectional view taken along a line B2-B2′ of FIG. 2A.

Referring to FIGS. 2A to 2C, a semiconductor memory according to an embodiment of the disclosed technology may include a substrate 200, a plurality of first conductive lines 210 formed over the substrate 200 and extending in a first direction, a plurality of second conductive lines 230 formed over the first conductive lines 210 to be spaced apart from the first conductive lines 210 and extending in a fourth direction substantially perpendicular to the first direction, and a plurality of memory cells 220 respectively overlapping intersection regions of the first conductive lines 210 and the second conductive lines 230 between the first conductive lines 210 and the second conductive lines 230.

The substrate 200 may include a semiconductor material such as silicon. A required lower structure (not shown), for example, a driving circuit that is electrically connected to the first conductive line 210 and/or the second conductive line 230 and drives them may be formed in the substrate 200.

The memory cell 220 may have a columnar shape and may function to store data. In the present embodiment, a case has been described in which the memory cell 220 has a circular shape in a plan view, but other implementations are also possible. In a plan view, the memory cell 220 may have various shapes, such as a rectangular shape, an elliptical shape, or others.

In an example, the memory cell 220 may include a variable resistance element that switches between different resistance states according to a voltage or current applied through a lower end connected to the first conductive line 210 and an upper end connected to the second conductive line 230 for storing different data. In an example, the memory cell 220 may include a multi-layer structure including a lower electrode layer 221, a selection element layer 223, an intermediate electrode layer 225, a variable resistance layer 227, and an upper electrode layer 229.

The lower electrode layer 221 and the upper electrode layer 229 may be located at both ends, for example, at lower and upper ends, respectively, of the memory cell 220 to transmit a voltage or current required for the operation of the memory cell 220. The intermediate electrode layer 225 may be interposed between the selection element layer 223 and the variable resistance layer 227 to physically separate them and electrically connect them. The lower electrode layer 221, the intermediate electrode layer 225, or the upper electrode layer 229 may include various conductive materials, for example, a metal such as platinum (Pt), tungsten (W), aluminum (Al), copper (Cu), tantalum (Ta) and titanium (Ti), a metal nitride such as titanium nitride (TiN) and tantalum nitride (TaN), or a combination thereof. Alternatively, for example, at least one of the lower electrode layer 221, the intermediate electrode layer 225, and the upper electrode layer 229 may include a carbon electrode.

The selection element layer 223 may function to reduce and/or suppress a leakage current between the memory cells MC sharing the first conductive line 210 or the second conductive line 230. In some implementations, the selection element layer 223 may have a threshold switching characteristic, for example, a characteristic for blocking or substantially limiting a current when a magnitude of an applied voltage is less than a predetermined threshold value and for allowing a current to abruptly increase above the threshold value. This threshold value may be referred to as a threshold voltage, and the selection element layer 223 may be implemented in a turned-on state or a turned-off state based on the threshold voltage. The selection element layer 223 may include a diode, an ovonic threshold switching (OTS) material such as a chalcogenide-based material, a mixed ionic electronic conducting (MIEC) material such as a metal-containing chalcogenide-based material, a metal insulator transition (MIT) material such as NbO₂ and VO₂, a tunneling insulating layer having a relatively wide band gap such as SiO₂, Al₂O₃, or others.

The variable resistance layer 227 may be a part that stores data in the memory cell 220. In some implementations, the variable resistance layer 227 may have a variable resistance characteristic that switches between different resistance states according to an applied voltage. The variable resistance layer 227 may have a single-layer structure or a multi-layer structure including at least one of materials used for an RRAM, a PRAM, an MRAM, an FRAM, or others. For example, the variable resistance layer 227 may include a metal oxide such as a perovskite-based oxide and a transition metal oxide, a phase change material such as a chalcogenide-based material, a ferromagnetic material, a ferroelectric material, or others.

FIG. 2D is a view showing a part of the memory cell of FIGS. 2A to 2C, which includes the variable resistance layer 227, the upper electrode layer 229, and the intermediate electrode layer 225.

Referring to FIG. 2D, the variable resistance layer 227 may include a pinned layer 227A, a free layer 227C, and a tunnel barrier layer 227B between the pinned layer 227A and the free layer 227C.

The pinned layer 227A may have a fixed magnetization direction. For example, as indicated by an arrow in the pinned layer 227A, the pinned layer 227A may have a magnetization direction that is perpendicular to the surface of the pinned layer 227A from top to bottom. However, the disclosed technology is not limited thereto, and in another embodiment, the pinned layer 227A may have a magnetization direction from bottom to top. Alternatively, in another embodiment, the pinned layer 227A may have a magnetization direction parallel to the surface of the pinned layer 227A. That is, the pinned layer 227A may have one of a right-to-left magnetization direction and a left-to-right magnetization direction. The free layer 227C may have a changeable magnetization direction. For example, as indicated by arrows in the free layer 227C, the free layer 227C may have a magnetization direction perpendicular to the surface of the free layer 227C from top to bottom or from bottom to top. However, when the pinned layer 227A has a magnetization direction parallel to the surface of the pinned layer 227A, the free layer 227C may also have a magnetization direction parallel to the surface of the free layer 227A, that is, a right-to-left magnetization direction or a left-to-right magnetization direction. The pinned layer 227A and the free layer 227C may have a single-layer structure or a multi-layer structure including various ferromagnetic materials, for example, Fe—Pt alloy, Fe—Pd alloy, Co—Pd alloy, Co—Pt alloy, Fe—Ni—Pt alloy, Co—Fe—Pt alloy, Co—Ni—Pt alloy, or others. The tunnel barrier layer 227B may be interposed between the pinned layer 227A and the free layer 227C, and may enable a change in the magnetization direction of the free layer 227C by allowing electrons to tunnel, if necessary, for example, during a program operation that changes the resistance state of the memory cell 220. The tunnel barrier layer 227B may have a single-layer structure or a multi-layer structure including an oxide such as MgO, CaO, SrO, TiO, VO, and NbO. In the present embodiment, although the case where the pinned layer 227A is positioned under the tunnel barrier layer 227B and the free layer 227C is positioned over the tunnel barrier layer 227B is illustrated, the disclosed technology is not limited thereto. In another embodiment, the positions of the pinned layer 227A and the free layer 227C may be changed. For example, the pinned layer 227A can be positioned over the tunnel barrier layer 227B and the free layer 227C is positioned under the tunnel barrier layer 227B.

In the variable resistance layer 227, the magnetization direction of the free layer 227C may be changed by a program current passing through the variable resistance layer 227. Accordingly, the magnetization direction of the free layer 227C and the magnetization direction of the pinned layer 227A may be parallel or antiparallel. When the magnetization direction of the free layer 227C and the magnetization direction of the pinned layer 227A are parallel, the memory cell 220 may have a low resistance state. Conversely, when the magnetization direction of the free layer 227C and the magnetization direction of the pinned layer 227A are antiparallel, the memory cell 220 may have a high resistance state.

In the example in FIGS. 2A to 2C, although the memory cell 220 includes the lower electrode layer 221, the selection element layer 223, the intermediate electrode layer 225, the variable resistance layer 227, and the upper electrode layer 229, as described above, the layer structure of the memory cell 220 is not limited to the described example in implementations and other implementations of the layer structure of the memory cell 220 are possible. For example, in certain implementations of the memory cell 220 with the variable resistance layer 227 for data storage, the stacking order of the layers of the memory cell 220 may be changed or at least one of the stacked layers may be omitted. As an example, one or more of the lower electrode layer 221, the intermediate electrode layer 225, and the upper electrode layer 229 may be omitted, or the positions of the selection element layer 223 and the variable resistance layer 227 may be reversed with each other. Alternatively, one or more layers (not shown) may be added to the memory cell 220 for process improvement or property improvement of the memory cell 220.

Assuming that imaginary lines forming a plurality of equilateral triangles exist in a plan view (refer to the dotted line in FIG. 2A) and the equilateral triangles are arranged such that six equilateral triangles form one equilateral hexagon, the plurality of memory cells 220 may be arranged to overlap the vertices of the equilateral triangles, respectively. Accordingly, the plurality of memory cells 220 may be arranged in lines along the first, second, and third directions parallel to the three sides of the equilateral triangle. The second direction may form an angle of substantially 60 degrees with respect to the first direction, and the third direction may form an angle of substantially 60 degrees with respect to the second direction. As a result, the pitch P2 of the memory cells 220 in the first direction, the second direction, and the third direction may have a constant value.

The first conductive line 210 may be disposed between the substrate 200 and the memory cell 220 to be connected to a lower end of the memory cell 220. The first conductive line 210 may have a single-layer structure or a multi-layer structure including various conductive materials, for example, a metal such as platinum (Pt), tungsten (W), aluminum (Al), copper (Cu), and tantalum (Ta), a metal nitride such as titanium nitride (TiN) and tantalum nitride (TaN), or a combination thereof. The first conductive line 210 may overlap the plurality of memory cells 220 arranged in the first direction by extending in the first direction. The plurality of first conductive lines 210 may be arranged to be spaced apart from each other in the fourth direction which corresponds to the width direction of the first conductive lines 210. In the fourth direction, the center of the first conductive line 210 and the center of the memory cell 220 may be arranged to substantially overlap. Such overlapping of the first conductive line 210 and the memory cell 220 in the fourth direction may be referred to as an on-pitch shape. In this case, the pitch P21 of the first conductive lines 210 may be smaller than the pitch P2 of the memory cells 220. As an example, when the pitch P2 of the memory cells 220 is 2F, the pitch P21 of the first conductive lines 210 may have a value of 2F*√3/2, that is, about 1.732F.

A space between the first conductive lines 210 may be filled with a first interlayer insulating layer ILD1, and a space between the memory cells 220 may be filled with a second interlayer insulating layer ILD2. The first interlayer insulating layer ILD1 and the second interlayer insulating layer ILD2 may include various insulating materials, for example, silicon oxide, silicon nitride, or a combination thereof.

The second conductive line 230 may be disposed over the memory cell 220 and the second interlayer insulating layer ILD2 to be connected to an upper end of the memory cell 220. The second conductive line 230 may have a single-layer structure or a multi-layer structure including various conductive materials, for example, a metal such as platinum (Pt), tungsten (W), aluminum (Al), copper (Cu), and tantalum (Ta), a metal nitride such as titanium nitride (TiN) and tantalum nitride (TaN), or a combination thereof. The second conductive line 230 may extend in the fourth direction to overlap the plurality of memory cells 220 arranged in the fourth direction, and may be arranged to be spaced apart from each other in the first direction. In this case, the plurality of memory cells 220 arranged in the fourth direction may be arranged in a zigzag manner without being positioned on a straight line extending in the fourth direction. This is because, as described above, the plurality of memory cells 220 are arranged in lines along the first direction, the second direction, and the third direction. Accordingly, the second conductive line 230 may only partially overlap each of the plurality of memory cells 220 arranged in the fourth direction. This will be described in more detail as follows.

When the plurality of memory cells 220 arranged in a line in the first direction are referred to as a column of memory cells 220, a plurality of columns of memory cells 220 may be arranged in the fourth direction. The plurality of columns of memory cells 220 may include one or more even-numbered columns and one or more odd-numbered columns. In the plan view of FIG. 2A, first and third columns of memory cells 220 from the top may correspond to the odd-numbered columns, and a second column of memory cells 220 from the top may correspond to the even-numbered column. The first and third columns may overlap the first and third first conductive lines 210 from the top, and the second column may overlap the second first conductive line 210 from the top. In this case, one of the second conductive lines 230 may overlap a first portion, for example, a right portion, of the memory cell 220 in the even-numbered column, and overlap a second portion, for example, a left portion, of the memory cells 220 in the odd-numbered column. Thus, when two memory cells at the odd-numbered column and the even-numbered column overlap a second conductive line 230, the left portion of the memory cell at the odd-numbered column overlaps the second conductive line 230 and the right portion of the memory cell at the even-numbered column overlaps the second conductive line 230. These right and left portions may be arranged to face each other. Accordingly, in a plan view, portions of the memory cells that are non-overlapping with the second conductive line 230 may be located outside the second conductive line 230. For example, a second portion, for example, a left portion of the memory cell 220 in the even-numbered column may protrude from the second conductive line 230 without overlapping the second conductive line 230. Also, in a plan view, a first portion, for example, a right portion of the memory cell 220 in the odd-numbered column may protrude from the second conductive line 230 without overlapping the second conductive line 230. As an example, the second conductive line 230 may overlap and connect to the right half of the memory cell 220 in the even-numbered column and the left half of the memory cell 220 in the odd-numbered column. However, other implementations are also possible beyond the specific examples disrobed in this patent document. For example, in some implementations, the second conductive line 230 partially overlaps the memory cells 220 arranged in the fourth direction and the overlapping area of the second conductive line 230 and the memory cell 220 may be variously modified. In some embodiments, a center line of the second conductive line 230 may be positioned between a center of the memory cell 220 in an odd-numbered column and a center of the memory cell 220 in an even-numbered column. The memory cells in the odd-numbered columns and the memory cells in the even-numbered columns may be alternately arranged along the extension direction of the second conductive line 230.

According to the present embodiment, the pitch P22 of the second conductive lines 230 may be substantially the same as the pitch P2 of the memory cells 220. When the pitch P2 of the memory cells 220 is 2F, the pitch P22 of the second conductive lines 230 may also have a value of 2F. The center of the second conductive line 230 and the center of the memory cell 220 may be misaligned from each other based on the first direction, for example, in an off-pitch shape.

An example of a method for manufacturing the semiconductor memory of the present embodiment is described as follows.

First, the first conductive lines 210 may be formed by depositing a conductive material over the substrate 200 and selectively etching the conductive material. A space between the first conductive lines 210 may be filled with an insulating material to form the first interlayer insulating layer ILD1.

Next, material layers for forming the memory cells 220 may be deposited over the first conductive lines 210 and the first interlayer insulating layer ILD1, and then the material layers may be selectively etched to form the memory cells 220. The selective etching of the material layers may be performed, for example, by an ion beam etching method. A space between the memory cells 220 may be filled with an insulating material to form the second interlayer insulating layer ILD2.

Next, the second conductive lines 230 may be formed by depositing a conductive material over the memory cells 220 and the second interlayer insulating layer ILD2 and selectively etching the conductive material.

According to the semiconductor memory described above, it is possible to prevent a decrease in the pitch P22 of the second conductive lines 230 while the pitch P2 of the memory cells 220 is constant. Accordingly, it is possible to eliminate defects in the etching process and improve the operating characteristics.

In the above embodiment, the case in which the first conductive line 210 is located below the memory cell 220 and the second conductive line 230 is located above the memory cell 220 has been described, but the upper and lower positions of the first conductive line 210 and the second conductive line 230 may be changed. For example, the second conductive line 230 extending in the fourth direction and partially overlapping the memory cell 220 may be positioned under the memory cell 220, and the first conductive line extending in the first direction may be positioned over the memory cell 220.

In the above embodiment, the fourth direction is substantially perpendicular to the first direction, but other implementations are also possible. The fourth direction may be perpendicular to the second direction or the third direction. In this case, the second conductive line 230 may extend along the fourth direction and partially overlaps the memory cells 220 arranged along the fourth direction.

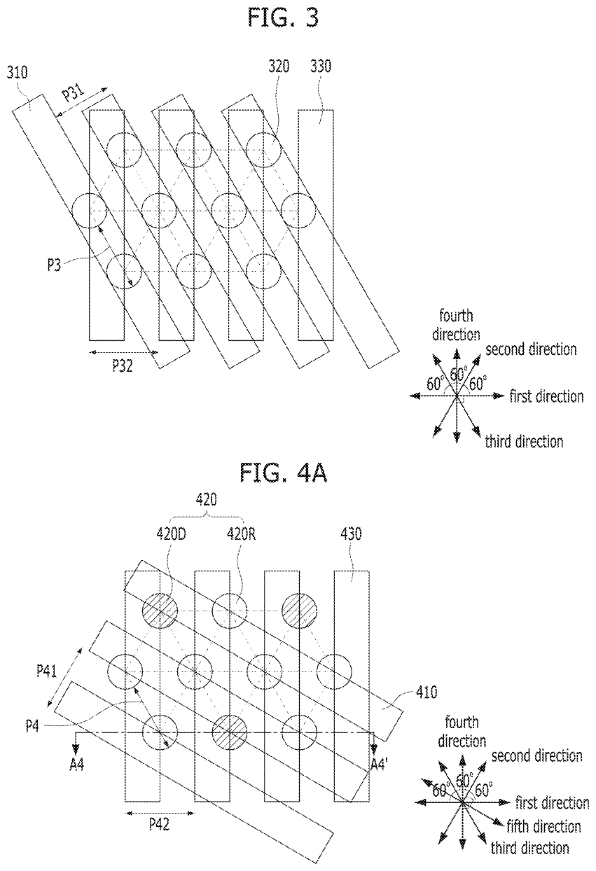

In the above embodiment, the first conductive line 210 extends in the first direction and overlaps the memory cells 220 arranged in the first direction has been described, but other implementations are also possible. In another embodiment, the first conductive line 210 may extend in the second direction or the third direction. This will be exemplarily described with reference to FIG. 3.

FIG. 3 is a plan view illustrating a semiconductor memory according to another embodiment of the disclosed technology. Differences from the above-described embodiment will be mainly described.

Referring to FIG. 3, the semiconductor memory according to the present embodiment may include a plurality of first conductive lines 310 extending in a third direction, a plurality of second conductive lines 330 formed to be spaced apart from the first conductive lines 310 and extending in a fourth direction, and plurality of memory cells 320 overlapping intersection regions of the first conductive lines 310 and the second conductive lines 330 between the first conductive lines 310 and the second conductive lines 330.

Assuming that there are imaginary lines forming a plurality of equilateral triangles in a plan view (refer to the dotted line of FIG. 3) and the equilateral triangles are arranged such that six equilateral triangles form one equilateral hexagon, the plurality of memory cells 320 may be arranged to overlap the vertices of the equilateral triangles, respectively. Accordingly, the plurality of memory cells 320 may be arranged in lines along a first direction, a second direction, and the third direction parallel to the three sides of the equilateral triangle, respectively. The second direction may form an angle of substantially 60 degrees with respect to the first direction, and the third direction may form an angle of substantially 60 degrees with respect to the second direction. As a result, the pitch P3 of the memory cells 320 in the first direction, the second direction, and the third direction may have a constant value. The fourth direction may be substantially perpendicular to the first direction.

The first conductive line 310 may be disposed to be connected to one of a lower end and an upper end of the memory cell 320. The first conductive line 310 may extend in the third direction to overlap the plurality of memory cells 320 arranged in the third direction. The plurality of first conductive lines 310 may be arranged to be spaced apart from each other in a direction perpendicular to the third direction which corresponds to the width direction of the first conductive line 310. In the width direction of the first conductive line 310, the center of the first conductive line 310 and the center of the memory cell 320 may be arranged to substantially overlap, that is, in an on-pitch shape. In this case, the pitch P31 of the first conductive lines 310 may be smaller than the pitch P3 of the memory cells 320. As an example, when the pitch P3 of the memory cells 320 is 2F, the pitch P31 of the first conductive lines 310 may have a value of 2F*√3/2, that is, about 1.732F.

The second conductive line 330 may be disposed to be connected to the other one of the lower and upper ends of the memory cell 320 that is not connected to the first conductive line 310. The second conductive line 330 may extend in the fourth direction to overlap the plurality of memory cells 320 arranged in the fourth direction, and may be arranged to be spaced apart from each other in the first direction. Since the plurality of memory cells 320 are not arranged in a line in the fourth direction, the second conductive line 330 may only partially overlap each of the plurality of memory cells 320 arranged in the fourth direction. As an example, one of the second conductive lines 330 may overlap a first portion, for example, a right portion of the memory cell 320 in an even-numbered column, and may overlap a second portion, for example, a left portion of the memory cell 320 in an odd-numbered column.

According to the present embodiment, the pitch P32 of the second conductive lines 330 may be substantially the same as the pitch P3 of the memory cells 320. That is, when the pitch P3 of the memory cells 320 is 2F, the pitch P32 of the second conductive lines 330 may also have a value of 2F. The center of the second conductive line 330 and the center of the memory cell 320 may be arranged to be misaligned from each other with respect to the first direction. Such misaligned arrangement of the two centers of the two elements, e.g., the center of the second conductive line 330 and the center of the memory cell 320, may be referred to as be in an off-pitch shape.

Unlike the present embodiment, the first conductive line 310 may extend in the second direction to overlap the plurality of memory cells 320 arranged in the second direction. In this case, the plurality of first conductive lines 310 may be arranged to be spaced apart from each other in a direction perpendicular to the second direction which corresponds to the width direction of the first conductive line 310, and the center of the first conductive line 310 and the center of the memory cell 320 may be arranged to substantially overlap in the width direction of the first conductive line 310, that is, in an on-pitch shape.

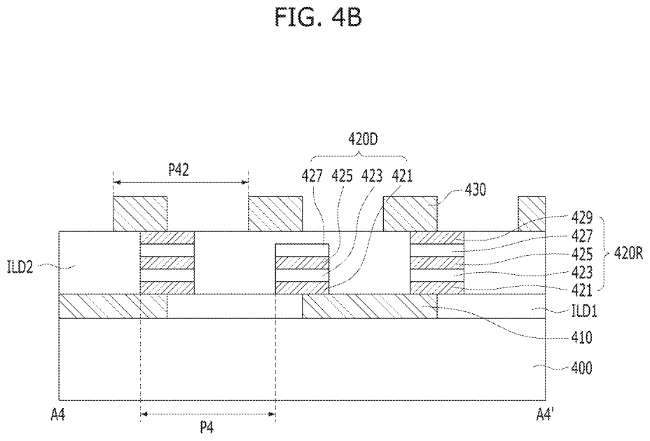

In the above embodiments, it has been described that the pitch reduction is prevented by arranging one of an upper conductive line and a lower conductive line in an off-pitch shape, but the disclosed technology is not limited thereto. In another embodiment, both the upper and lower conductive lines may be arranged in an off-pitch shape. This will be exemplarily described with reference to FIGS. 4A and 4B.

FIG. 4A is a plan view illustrating a semiconductor memory according to another embodiment of the disclosed technology, and FIG. 4B is a cross-sectional view taken along a line A4-A4′ of FIG. 4A. Differences from the above-described embodiments will be mainly described.

Referring to FIGS. 4A to 4C, the semiconductor memory according to the present embodiment may include a substrate 400, a plurality of first conductive lines 410 formed over the substrate 400 and extending in a fifth direction, a plurality of second conductive lines 430 formed over the first conductive lines 410 to be spaced apart from the first conductive lines 410 and extending in a fourth direction, and a plurality of memory cells 420 overlapping intersection regions of the first conductive lines 410 and the second conductive lines 430 between the first conductive lines 410 and the second conductive lines 430.

The memory cells 420 may include a regular memory cell 420R that performs a function of storing data and a dummy memory cell 420D that does not electrically perform any function.

As an example, the regular memory cell 420R may include a variable resistance element that switches between different resistance states according to a voltage or current applied through a lower end connected to the first conductive line 410 and an upper end connected to the second conductive line 430 for storing different data. Further, as an example, the regular memory cell 420R may have a multi-layer structure including a lower electrode layer 421, a selection element layer 423, an intermediate electrode layer 425, a variable resistance layer 427, and an upper electrode layer 429. The dummy memory cell 420D may be disconnected from at least one of the first conductive line 410 and the second conductive line 430 to prevent an electrical function from being performed. To this end, the dummy memory cell 420D may have the same structure as a structure in which at least one of the lower electrode layer 421 and the upper electrode layer 429 is omitted from the regular memory cell 420R. As an example, as shown, the dummy memory cell 420D may have a structure in which the upper electrode layer 429 is omitted from the regular memory cell 420R, and thus may have the lower electrode layer 421, the selection element layer 423, the intermediate electrode layer 425, and the variable resistance layer 427. In this case, since the upper end of the dummy memory cell 420D is covered by the second interlayer insulating layer ILD2, the dummy memory cell 420D and the second conductive line 430 may be electrically insulated. However, the disclosed technology is not limited thereto, and in another embodiment, the dummy memory cell 420D may have a structure in which the lower electrode layer 421 is omitted from the regular memory cell 420R, or a structure in which the lower electrode layer 421 and the upper electrode layer 429 are omitted from the regular memory cell 420R. When the dummy memory cell 420D has a structure in which the lower electrode layer 421 is omitted from the regular memory cell 420R, the dummy memory cell 420D may be electrically insulated from the first conductive line 410. When the dummy memory cell 420D has a structure in which the lower electrode layer 421 and the upper electrode layer 429 are omitted from the regular memory cell 420R, the dummy memory cell 420D may be electrically insulated from the first conductive line 410 and the second conductive line 430.

Assuming that there are imaginary lines forming a plurality of equilateral triangles in a plan view (refer to the dotted line in FIG. 4A) and the equilateral triangles are arranged such that six equilateral triangles form one equilateral hexagon, the plurality of memory cells 420 may be arranged to overlap the vertices of the equilateral triangles, respectively. Accordingly, the plurality of memory cells 420 may be arranged along each of the first, second, and third directions parallel to the three sides of the equilateral triangle. The second direction may form an angle of substantially 60 degrees with respect to the first direction, and the third direction may form an angle of substantially 60 degrees with respect to the second direction. As a result, the pitch P4 of the memory cells 420 in the first direction, the second direction, and the third direction may have a constant value. The fourth direction may be substantially perpendicular to the first direction, and the fifth direction may be substantially perpendicular to the second direction.

The first conductive line 410 may be disposed between the substrate 400 and the memory cell 420. The first conductive line 410 may include various conductive materials, for example, a metal such as platinum (Pt), tungsten (W), aluminum (Al), copper (Cu), and tantalum (Ta), a metal nitride such as titanium nitride (TiN) and tantalum nitride (TaN), or a combination thereof, and may have a single-layer structure or a multi-layer structure. The first conductive lines 410 may extend in the fifth direction to overlap the plurality of memory cells 420 arranged in the fifth direction, and may be arranged to be spaced apart from each other in the second direction, that is, in the width direction of the first conductive line 410. In this case, the plurality of memory cells 420 arranged in the fifth direction may not be arranged in a straight line extending in the fifth direction, but may be arranged in a zigzag manner. Accordingly, the first conductive line 410 may only partially overlap each of the plurality of memory cells 420 arranged in the fifth direction.

More specifically, when the plurality of memory cells 420 arranged in a line in the second direction are referred to as a column of the memory cells 420, a plurality of columns of memory cells 420 may be arranged in the fifth direction. When the plurality of columns of memory cells 420 include one or more even-numbered columns and one or more odd-numbered columns, one of the first conductive lines 410 may overlap a first portion, for example, a right portion of the memory cell 420 in the odd-numbered column, and may overlap a second portion, for example, a left portion of the memory cell 420 in the even-numbered column. Accordingly, a second portion, for example, a left portion, excluding the first portion of the memory cell 420 in the odd-numbered column, may protrude outside the first conductive line 410 without overlapping the first conductive line 410. Also, a first portion, for example, a right portion, excluding the second portion of the memory cell 420 in the even-numbered column, may protrude outside the first conductive line 410 without overlapping the first conductive line 410.

According to the present embodiment, the pitch P41 of the first conductive lines 410 may be substantially the same as the pitch P4 of the memory cells 420. That is, when the pitch P4 of the memory cells 420 is 2F, the pitch P41 of the first conductive lines 410 may also have a value of 2F. However, in the second direction, the center of the first conductive line 410 and the center of the memory cell 420 may be arranged to be misaligned from each other, that is, in an off-pitch shape.

A space between the first conductive lines 410 may be filled with a first interlayer insulating layer ILD1, and a space between the memory cells 420 may be filled with a second interlayer insulating layer ILD2.

The second conductive lines 430 may be disposed over the memory cells 420 and the second interlayer insulating layer ILD2. The second conductive line 430 may include various conductive materials, for example, a metal such as platinum (Pt), tungsten (W), aluminum (Al), copper (Cu), and tantalum (Ta), a metal nitride such as titanium nitride (TiN) and tantalum nitride (TaN), or a combination thereof, and may have a single-layer structure or a multi-layer structure. The second conductive line 430 may extend in the fourth direction to overlap the plurality of memory cells 420 arranged in the fourth direction, and may be arranged to be spaced apart from each other in the first direction. In this case, the plurality of memory cells 420 arranged in the fourth direction may not be positioned in a straight line extending in the fourth direction but may be arranged in a zigzag manner. Accordingly, the second conductive line 430 may only partially overlap each of the plurality of memory cells 420 arranged in the fourth direction.

More specifically, when a plurality of memory cells 420 arranged in a line in the first direction are referred to as a column of memory cells 420, a plurality of columns of memory cells 420 may be arranged in the fourth direction. When the plurality of columns of memory cells 420 include one or more even-numbered columns and one or more odd-numbered columns, one of the second conductive lines 430 may overlap a first portion, for example, a right portion of the memory cell 420 in the even-numbered column, and may overlap a second portion, for example, a left portion of the memory cell 420 in the odd-numbered column. Accordingly, a second portion, for example, a left portion, excluding the first portion of the memory cell 420 in the even-numbered column may protrude outside the second conductive line 430 without overlapping the second conductive line 430, and a first portion, for example, a right portion, excluding the second portion of the memory cell 420 in the odd-numbered column may protrude outside the second conductive line 430 without overlapping the second conductive line 430.

According to the present embodiment, the pitch P42 of the second conductive lines 430 may be substantially the same as the pitch P4 of the memory cells 420. That is, when the pitch P4 of the memory cells 420 is 2F, the pitch P42 of the second conductive lines 430 may also have a value of 2F. However, the center of the second conductive line 430 and the center of the memory cell 420 may be arranged to be misaligned from each other in the first direction, that is, in an off-pitch shape.

That is, according to the present embodiment, it may be possible to prevent reduction of the pitch P41 of the first conductive lines 410 and the pitch P42 of the second conductive lines 430.

However, in this case, since the two memory cells 420 are positioned at the intersection region of one of the first conductive lines 410 and one of the second conductive lines 430, one of the two memory cells 420 may be used as the regular memory cell 420R and the other of the two memory cells 420 may be used as the dummy memory cell 420D. In this case, since only the regular memory cell 420R of the two memory cells 420 operates, there may be no problem in the operation of the semiconductor memory.

A method for manufacturing the semiconductor memory of the present embodiment will be briefly described as follows.

First, the first conductive lines 410 may be formed by depositing a conductive material over the substrate 400 and selectively etching the conductive material. A space between the first conductive lines 410 may be filled with an insulating material to form the first interlayer insulating layer ILD1.

Next, material layers for forming the memory cells 420 may be deposited over the first conductive lines 410 and the first interlayer insulating layer ILD1, and the material layers may be selectively etched to form the memory cells 420. The selective etching of the material layers may be performed, for example, by an ion beam etching method.

Next, after forming an insulating material filling a space between the memory cells 420, at least one of the material layers in the region where the dummy memory cell 420D is to be formed, for example, a conductive layer for forming the upper electrode layer 429 may be removed through a mask and etching process. Then, the space from which the conductive layer is removed may be filled with an additional insulating material. The insulating material and the additional insulating material may form the second interlayer insulating layer ILD2.

Next, the second conductive lines 430 may be formed by depositing a conductive material over the memory cells 420 and the second interlayer insulating layer ILD2 and selectively etching the conductive material.

In the above embodiment, the first conductive line 410 is positioned below the memory cell 420 and the second conductive line 430 is positioned above the memory cell 420. However, other implementations are also possible such that the upper and lower positions of the first conductive line 410 and the second conductive line 430 may be changed. For example, the second conductive line 430 extending in the fourth direction may be positioned below the memory cell 420, and the first conductive line 410 extending in the fifth direction may be positioned above the memory cell 420.

In the above embodiment, the fifth direction is substantially perpendicular to the second direction, but other implementations are also possible. For example, the fifth direction may be substantially perpendicular to the third direction. In this case, the first conductive line 410 may extend in the fifth direction and partially overlap the memory cells 420 arranged in the fifth direction.

While this patent document contains many specifics in the disclosed examples, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few embodiments and examples are described. Other embodiments, enhancements and variations can be made based on what is described and illustrated in this patent document.

What is claimed is:

1. A semiconductor device, comprising:
a plurality of conductive lines extending in a first direction; and
a plurality of memory cells arranged in a plurality of columns extending in a second direction intersecting the first direction,
wherein the plurality of columns include odd-numbered columns and even-numbered columns,
wherein a specific conductive line among the plurality of conductive lines partially overlaps a first portion of a memory cell in one of the odd-numbered columns and a second portion of a memory cell in one of the even-numbered columns, and
wherein the first portion and the second portion face each other with respect to a center line of the specific conductive line.

2. The semiconductor device of claim 1, wherein the plurality of memory cells are arranged in rows extending in a first direction, a second direction, and a third direction, and the second direction and the third direction each form an angle of about 60 degrees with respect to the first direction.

3. The semiconductor device of claim 2, wherein the plurality of memory cells are positioned at vertices of imaginary equilateral triangles.

4. The semiconductor device of claim 3, wherein the plurality of memory cells form a plurality of equilateral hexagons including six equilateral triangles.

5. The semiconductor device of claim 1, wherein the first portion comprises a left portion of the memory cell in the odd-numbered column, and the second portion comprises a right portion of the memory cell in the even-numbered column.

6. The semiconductor device of claim 5, wherein a remaining portion of the memory cell in the odd-numbered column protrudes beyond the specific conductive line without overlapping the specific conductive line.

7. The semiconductor device of claim 6, wherein a remaining portion of the memory cell in the even-numbered column protrudes beyond the specific conductive line without overlapping the specific conductive line.

8. The semiconductor device of claim 1, wherein centers of the plurality of memory cells arranged in the odd-numbered columns are offset from centers of the plurality of memory cells arranged in the even-numbered columns in the first direction.

9. The semiconductor device of claim 1, wherein the plurality of memory cells arranged in the odd-numbered columns and the plurality of memory cells arranged in the even-numbered columns are alternately disposed along a direction of extension of the specific conductive line.

10. The semiconductor device of claim 9, wherein the specific conductive line overlaps the first portion of the memory cell in the odd-numbered column and the second portion of the memory cell in the even-numbered column.

11. The semiconductor device of claim 1, wherein a center line of the specific conductive line is positioned between a center of the memory cell in the odd-numbered column and a center of the memory cell in the even-numbered column.

12. The semiconductor device of claim 1, wherein the specific conductive line is configured to overlap the plurality of memory cells arranged along a direction of extension of the specific conductive line.

13. The semiconductor device of claim 1, wherein a center of the specific conductive line is misaligned with a center of the memory cell overlapped by the specific conductive line in the first direction.

14. The semiconductor device of claim 1, wherein a pitch of the plurality of memory cells in the first direction is equal to a pitch of the plurality of memory cells in the second direction.

15. The semiconductor device of claim 14, wherein the pitch of the plurality of memory cells in the second direction is equal to a pitch of the plurality of memory cells in a third direction intersecting the first direction and the second direction.
